(19) United States
(12) Patent Application Publication
(10) Pub. No.: US 2020/0199431 A1
(43) Pub. Date: Jun. 25, 2020

(54) HEAT DISSIPATION SHEET AND HEAT DISSIPATION SHEET-ATTACHED DEVICE

(71) Applicant: FUJIFILM Corporation, Tokyo (JP)

(72) Inventors: Satoshi KUNIYASU, Minami-ashigara-shi (JP); Takayuki SANO, Minami-ashigara-shi (JP)

(73) Assignee: FUJIFILM Corporation, Tokyo (JP)

(21) Appl. No.: 16/810,118

(22) Filed: Mar. 5, 2020

Related U.S. Application Data
(63) Continuation of application No. PCT/JP2018/033039, filed on Sep. 6, 2018.

(30) Foreign Application Priority Data
Sep. 28, 2017 (JP) 2017-188035

(51) Int. Cl. C09K 5/14; C08K 3/38; H05K 7/20; F28F 13/18

(52) U.S. Cl. CPC C09K 5/14; C08K 3/38; H05K 7/2039; C08K 2201/001; C08K 2003/385; C08K 2201/005; F28F 13/18

(57) ABSTRACT

An object of the present invention is to provide a heat dissipation sheet having an excellent heat dissipation property and a heat dissipation sheet-attached device in which the heat dissipation sheet is used. The heat dissipation sheet of the present invention contains a resin binder and inorganic particles, the inorganic particles include inorganic particles A having a particle diameter of 100 μm or less and inorganic particles B having a particle diameter of more than 100 μm, 80% or more of all of the inorganic particles A are present in a region X from one surface of the heat dissipation sheet to ⅓ of an overall thickness of the heat dissipation sheet in a thickness direction, and 70% or more of all of the inorganic particles B are present in a region Y from the other surface of the heat dissipation sheet to ⅔ of the overall thickness of the heat dissipation sheet in the thickness direction.

### CROSS-REFERENCE TO RELATED APPLICATIONS

This application is a Continuation of PCT International Application No. PCT/JP2018/033039 filed on Sep. 6, 2018, which claims priority under 35 U.S.C. § 119(a) to Japanese Patent Application No. 2017-188035 filed on Sep. 28, 2017. The above application is hereby expressly incorporated by reference, in its entirety, into the present application.

### BACKGROUND OF THE INVENTION

### 1. Field of the Invention

The present invention relates to a heat dissipation sheet and a heat dissipation sheet-attached device.

### 2. Description of the Related Art

In recent years, together with efforts to decrease the sizes, increase the densities, and increase the powers of electronic devices and semiconductors, attempts for further integrating members configuring the electronic devices and the semiconductors have been underway. In a highly integrated device, a variety of members are tightly disposed in a limited space without a gap therebetween, and thus it becomes difficult to dissipate heat generated in the device, and there is a case where the device becomes relatively hot. Particularly, some of semiconductor elements such as a central processing unit (CPU) and a power device; light emitting diode (LED) backlights; batteries; and the like emit heat of approximately 150° C. or higher, and it is known that there is a case where the accumulation of such heat in the device causes a disadvantage of the occurrence of the malfunction of the device attributed to the heat.

As a method for dissipating heat in a device, a method of using a heat sink is known. In addition, a method in which the device and the heat sink are adhered to each other using a heat dissipation sheet in order to efficiently transfer heat in the device to the heat sink is known.

As such a heat dissipation sheet, for example, JP2009-197185A describes a transparent thermally conductive adhesive film including a resin and transparent or white fine particles having two or more peaks in the particle size distribution ([claim 1]).

In addition, JP2013-189625A describes a highly thermally conductive semi-cured resin film containing a resin in a semi-cured state and a filler satisfying a predetermined average particle diameter ([claim 6]).

In addition, JP2016-014090A describes a thermally adhesive sheet having a thermally adhesive layer (A) containing a thermal adhesive (al) and a thermally conductive filler (a2) ([claim 1]).

### SUMMARY OF THE INVENTION

As a result of studying JP2009-197185A, JP2013-189625A, and JP2016-014090A, the present inventors clarified that, for the current devices that are highly integrated, there is room for improvement in a heat dissipation property.

Therefore, an object of the present invention is to provide a heat dissipation sheet having an excellent heat dissipation property and a heat dissipation sheet-attached device in which the heat dissipation sheet is used.

As a result of intensive studies for attaining the above-described object, the present inventors found that a heat dissipation sheet having an excellent heat dissipation property is obtained by unevenly distributing inorganic particles having a predetermined particle diameter and completed the present invention.

That is, it was found that the above-described object can be attained by the following configurations.

[1] A heat dissipation sheet comprising: a resin binder; and inorganic particles,

in which the inorganic particles include inorganic particles A having a particle diameter of 100 μm or less and inorganic particles B having a particle diameter of more than 100 μm,

80% or more of all of the inorganic particles A are present in a region X from one surface of the heat dissipation sheet to ⅓ of an overall thickness of the heat dissipation sheet in a thickness direction, and

70% or more of all of the inorganic particles B are present in a region Y from the other surface of the heat dissipation sheet to ⅔ of the overall thickness of the heat dissipation sheet in the thickness direction.

[2] The heat dissipation sheet according to [1], in which the thickness is 200 to 300 μm.

[3] The heat dissipation sheet according to [1] or [2], in which a content of the inorganic particles A is 5 to 150 parts by mass with respect to 100 parts by mass of the resin binder.

[4] The heat dissipation sheet according to any one of [1] to [3], in which a content of the inorganic particles B is 50 to 500 parts by mass with respect to 100 parts by mass of the resin binder.

[5] The heat dissipation sheet according to any one of [1] to [4], in which the inorganic particle is at least one inorganic substance selected from the group consisting of an inorganic nitride and an inorganic oxide.

[6] The heat dissipation sheet according to [5], in which the inorganic nitride contains at least one selected from the group consisting of boron nitride and aluminum nitride.

[7] The heat dissipation sheet according to [5], in which the inorganic oxide contains at least one selected from the group consisting of titanium oxide, aluminum oxide, and zinc oxide.

[8] The heat dissipation sheet according to any one of [1] to [7], in which the resin binder is a cured substance obtained by curing a curable composition containing a polymerizable monomer.

[9] The heat dissipation sheet according to [8], in which the polymerizable monomer has at least one polymerizable group selected from the group consisting of an acryloyl group, a methacryloyl group, an oxiranyl group, and a vinyl group.

[10] A heat dissipation sheet-attached device comprising: a device; and the heat dissipation sheet according to any one of [1] to [9] disposed on the device.

According to the present invention, it is possible to provide a heat dissipation sheet having an excellent heat dissipation property and a heat dissipation sheet-attached device in which the heat dissipation sheet is used.

### BRIEF DESCRIPTION OF THE DRAWINGS

FIG. 1 is a schematic cross-sectional view showing an example of a heat dissipation sheet of the present invention.

### DESCRIPTION OF THE PREFERRED EMBODIMENTS

Hereinafter, the present invention will be described in detail.

There will be a case where a configurational requirement described below is described on the basis of a typical embodiment of the present invention, but the present invention is not limited to such an embodiment.

In the present specification, a numeric range expressed using “to” refers to a range including numeric values before and after “to” as the lower limit value and the upper limit value.

[Heat Dissipation Sheet]

A heat dissipation sheet of an embodiment of the present invention is a heat dissipation sheet containing a resin binder and inorganic particles.

In addition, in the heat dissipation sheet of the embodiment of the present invention, the inorganic particles include inorganic particles A having a particle diameter of 100 μm or less and inorganic particles B having a particle diameter of more than 100 μm.

In addition, in the heat dissipation sheet of the embodiment of the present invention, 80% or more of all of the inorganic particles A are present in a region X from one surface of the heat dissipation sheet to ⅓ of the overall thickness of the heat dissipation sheet in the thickness direction (hereinafter, also simply referred to as “region X”), and 70% or more of all of the inorganic particles B are present in a region Y from the other surface of the heat dissipation sheet to ⅔ of the overall thickness of the heat dissipation sheet in the thickness direction (hereinafter, also simply referred to as “region Y”).

In the heat dissipation sheet of the embodiment of the present invention, regarding the inorganic particles that are contained together with the resin binder, 80% or more of all of the inorganic particles A having a particle diameter of 100 μm or less are present in the region X, and 70% or more of all of the inorganic particles B having a particle diameter of more than 100 μm are present in the region Y, whereby the heat dissipation property becomes favorable.

The reason for such an effect being exhibited is not clear in detail, but the present inventors assume as described below.

That is, it is considered that, in a case where the inorganic particles B having a particle diameter of more than 100 μm are unevenly distributed in the region Y, interfaces in which the inorganic particles B are in contact with the resin binder and the inorganic particles A decrease, the inorganic particles B serve as principal heat transfer paths, and heat from a device can be efficiently conducted.

In addition, it is considered that, in a case where the inorganic particles A having a particle diameter of 100 μm or less are unevenly distributed in the region X, a gap is not easily generated in the case of joining the region X-side surface to a device or a heat sink, and heat can be efficiently conducted.

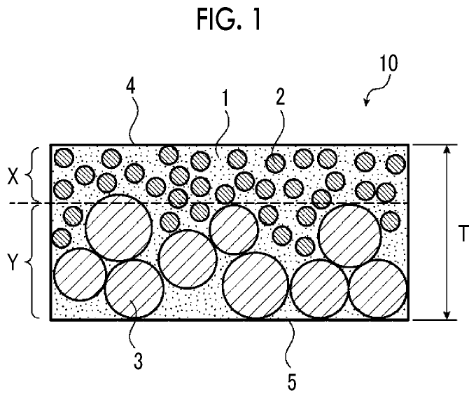

FIG. 1 shows a schematic cross-sectional view showing an example of the heat dissipation sheet of the embodiment of the present invention.

A heat dissipation sheet 10 shown in FIG. 1 contains a resin binder 1, inorganic particles A2 having a particle diameter of 100 μm or less, and inorganic particles B3 having a particle diameter of more than 100 μm.

In addition, in the heat dissipation sheet 10 shown in FIG. 1, 80% or more of all of the inorganic particles A2 are present in the region X from one surface 4 of the heat dissipation sheet 10 to ⅓ of an overall thickness T of the heat dissipation sheet 10 in the thickness direction, and 70% or more of all of the inorganic particles B are present in the region Y from the other surface 5 of the heat dissipation sheet 10 to ⅔ of the overall thickness T of the heat dissipation sheet in the thickness direction.

Hereinafter, the resin binder and the inorganic particles that are included in the heat dissipation sheet of the embodiment of the present invention will be described in detail.

[Resin Binder]

The resin binder that is included in the heat dissipation sheet of the embodiment of the present invention is not particularly limited, and, it is possible to use, for example, an epoxy resin, a phenol resin, a polyimide resin, a cresol resin, a melamine resin, an unsaturated polyester resin, an isocyanate resin, a polyurethane resin, a polybutylene terephthalate resin, a polyethylene terephthalate resin, a polyphenylene sulfide resin, a fluorine resin, or a polyphenylene oxide resin. Among these resins, an epoxy resin having a small thermal expansion rate and being excellent in terms of heat resistance and adhesiveness is preferred.

As the epoxy resin, specifically, for example, a bifunctional epoxy resin such as a bisphenol A-type epoxy resin, a bisphenol F-type epoxy resin, or a bisphenol S-type epoxy resin; a novolac-type epoxy resin such as a phenol novolac-type epoxy resin or a cresol novolac-type epoxy resin; and the like are exemplified.

In the present invention, the resin binder is preferably a cured substance obtained by curing a curable composition containing a polymerizable monomer since it is easy to add a function such as heat resistance.

Here, the polymerizable monomer refers to a compound that has a polymerizable group and cures by a predetermined treatment in which heat, light, or the like is used.

In addition, as the polymerizable group that the polymerizable monomer has, for example, at least one polymerizable group selected from the group consisting of an acryloyl group, a methacryloyl group, an oxiranyl group, and a vinyl group is exemplified.

The number of the polymerizable groups included in the polymerizable monomer is not particularly limited, but is preferably 2 or more and more preferably 3 or more from the viewpoint of the excellent heat resistance of the cured substance obtained by curing the curable composition. The upper limit is not particularly limited, but is 8 or less in many cases.

The kind of the polymerizable monomer is not particularly limited, and it is possible to use a well-known polymerizable monomer. For example, an epoxy resin monomer and an acrylic resin monomer described in Paragraph [0028] of JP4118691B; an epoxy compound described in Paragraphs [0006] to [0011] of JP2008-013759A; an epoxy resin mixture described in Paragraphs [0032] to [0100] of JP2013-227451A; and the like are exemplified.

The content of the polymerizable monomer in the curable composition is not particularly limited, and an optimal content is appropriately selected depending on the use of the curable composition. Particularly, the content of the polymerizable monomer is preferably 10% to 90% by mass, more preferably 15% to 70% by mass, and still more preferably 20% to 60% by mass of the total solid content of the curable composition.

The curable composition may include one kind of polymerizable monomer or may include two or more kinds of polymerizable monomers.

[Inorganic Particles]

The inorganic particles that are included in the heat dissipation sheet of the embodiment of the present invention include inorganic particles A having a particle diameter of 100 μm or less and inorganic particles B having a particle diameter of more than 100 μm, and, as described above, 80% or more of all of the inorganic particles A are present in the region X, and 70% or more of all of the inorganic particles B are present in the region Y.

Here, the particle diameter refers to a cross-sectional diameter (a long diameter in a case where the particle is not truly circular) of an inorganic particle shown in an SEM image obtained by capturing a cross section in the thickness direction of the heat dissipation sheet using a scanning electron microscope (SEM).

In addition, in the present invention, the presence proportion in the region X or the region Y refers to a proportion measured in the following order. First, a cross section in the thickness direction of the heat dissipation sheet is captured using SEM, inorganic particles shown in the obtained SEM image are classified into the inorganic particles A and the inorganic particles B, and the total numbers of the respective types of particles are counted. Next, the number of the inorganic particles A present in the region X on the SEM image is counted, and the proportion in all of the inorganic particles A is computed. Similarly, the number of the inorganic particles B present in the region Y on the SEM image is counted, and the proportion in all of the inorganic particles B is computed. These measurement and computation are carried out on the cross sections of 10 random places, and the average value of the respective obtained computation results is computed as the presence proportion.

In addition, in the present invention, the inorganic particles are preferably at least one kind of inorganic substance selected from the group consisting of an inorganic nitride and an inorganic oxide since the heat dissipation property of a heat dissipation sheet to be obtained becomes more favorable.

The inorganic nitride is not particularly limited, for example, boron nitride (BN), carbon nitride (C₃N₄), silicon nitride (Si₃N₄), gallium nitride (GaN), indium nitride (InN), aluminum nitride (AlN), chromium nitride (Cr₂N), copper nitride (Cu₃N), iron nitride (Fe₄N or Fe₃N), lanthanum nitride (LaN), lithium nitride (Li₃N), magnesium nitride (Mg₃N₂), molybdenum nitride (Mo₂N), niobium nitride (NbN), tantalum nitride (TaN), titanium nitride (TiN), tungsten nitride (W₂N, WN₂ or WN), yttrium nitride (YN), zirconium nitride (ZrN), and the like are exemplified, and these inorganic nitrides may be singly used or two or more inorganic nitrides may be jointly used.

In addition, the inorganic nitride preferably includes at least one kind of atom selected from the group consisting of a boron atom, an aluminum atom, and a silicon atom since the heat dissipation property of a heat dissipation sheet to be obtained becomes more favorable. More specifically, the inorganic nitride is more preferably at least one kind selected from the group consisting of boron nitride, aluminum nitride, and silicon nitride and still more preferably at least one kind selected from the group consisting of boron nitride and aluminum nitride.

The inorganic oxide is not particularly limited, for example, zirconium oxide (ZrO₂), titanium oxide (TiO₂), silicon oxide (SiO₂), aluminum oxide (Al₂O₃), iron oxide (Fe₂O₃, FeO, Fe₃O₄), copper oxide (CuO, Cu₂O), zinc oxide (ZnO), yttrium oxide (Y₂O₃), niobium oxide (Nb₂O₅), molybdenum oxide (MoO₃), indium oxide (In₂O₃, In₂O), tin oxide (SnO₂), tantalum oxide (Ta₂O₅), tungsten oxide (WO₃, W₂O₅), lead oxide (PbO, PbO₂), bismuth oxide (Bi₂O₃), cerium oxide (CeO₂, Ce₂O₃), antimony oxide (Sb₂O₃, Sb₂O₅), germanium oxide (GeO₂, GeO), lanthanum oxide (La₂O₃), ruthenium oxide (RuO₂), and the like are exemplified, and these inorganic oxides may be singly used or two or more inorganic oxides may be jointly used.

The inorganic oxide preferably includes at least one kind selected from the group consisting of titanium oxide, aluminum oxide, and zinc oxide since the heat dissipation property of a heat dissipation sheet to be obtained becomes more favorable.

The inorganic oxide may be an oxide that is generated by the oxidation of metal prepared as a non-oxide in an environment or the like.

In the present invention, among the above-described inorganic particles, 80% or more of all of the inorganic particles A having a particle diameter of 100 μm or less are present in the region X, 90% to 100% are preferably present in the region X, and 95% to 100% are more preferably present in the region X.

In addition, the content of the inorganic particles A is preferably 5 to 150 parts by mass with respect to 100 parts by mass of the resin binder since the heat dissipation property of a heat dissipation sheet to be obtained becomes more favorable.

In addition, in the present invention, among the above-described inorganic particles, 70% or more of all of the inorganic particles B having a particle diameter of more than 100 μm are present in the region Y, and 75% to 100% are preferably present in the region Y.

In addition, the content of the inorganic particles B is preferably 50 to 500 parts by mass, more preferably 100 to 300 parts by mass, and still more preferably 150 to 300 parts by mass with respect to 100 parts by mass of the resin binder since the heat dissipation property of a heat dissipation sheet to be obtained becomes more favorable.

The thickness of the heat dissipation sheet of the embodiment of the present invention is preferably 200 to 300 μm, more preferably 200 to 280 μm, and still more preferably 200 to 250 μm since the adhesiveness becomes more favorable and the heat dissipation property also becomes more favorable.

Here, the thickness of the heat dissipation sheet refers to a value obtained by measuring the thicknesses of the heat dissipation sheet at random 10 points and arithmetically averaging the measured thicknesses.

[Production Method]

As a method for producing the heat dissipation sheet of the embodiment of the present invention, for example, a method having a step of applying a composition containing the resin binder and the inorganic particles B having a particle diameter of more than 100 μm (hereinafter, also abbreviated as “resin composition B”) onto a substrate or a release liner (hereinafter, also collectively referred to as “base material”), forming and then curing a coated film, thereby forming a cured film (hereinafter, also abbreviated as “cured film Y”) and a step of applying a composition containing the resin binder and the inorganic particles A having a particle diameter of 100 μm or less (hereinafter, also abbreviated as “resin composition A”) onto the cured film Y, forming and then curing a coated film, thereby forming a cured film (hereinafter, also abbreviated as “cured film X”);

a method having a step of applying the resin composition B onto the base material to form a coated film (hereinafter, also abbreviated as “coated film Y”), a step of applying the resin composition A onto the coated film Y to form a coated film (hereinafter, also abbreviated as “coated film X”), and a step of curing the coated film Y and the coated film X to form cured films; and the like are exemplified.

<Base Material>

(Substrate)

As the substrate, specifically, for example, metal substrates of iron, copper, stainless steel, aluminum, a magnesium-containing alloy, an aluminum-containing alloy, or the like are preferably exemplified. Among these, a copper substrate is preferred.

(Release Liner)

As the release liner, specifically, it is possible to use, for example, paper such as kraft paper, glassine paper, or high-quality paper; a resin film such as polyethylene, polypropylene, or polyethylene terephthalate (PET); laminated paper in which the above-described paper and resin film are laminated; a liner obtained by carrying out a release treatment of a silicone-based resin or the like on a single surface or both surfaces of the above-described paper on which a sealing treatment is carried out with clay, polyvinyl alcohol, or the like; or the like.

<Resin Composition>

The resin composition A and the resin composition B (hereinafter, collectively abbreviated as “resin composition” in the case of being not particularly differentiated from each other) may contain, together with the resin binder and the inorganic particles, the above-described polymerizable monomer and a curing agent, a curing accelerator, a polymerization initiator, and a solvent which will be described below.

(Curing Agent)

The kind of a random curing agent is not particularly limited, for example, a compound having a functional group selected from the group consisting of a hydroxy group, an amino group, a thiol group, an isocyanate group, a carboxy group, an acryloyl group, a methacryloyl group, and a carboxylic anhydride group is preferred, and the compound more preferably has a functional group selected from the group consisting of a hydroxy group, an acryloyl group, a methacryloyl group, an amino group, and a thiol group.

The number of the functional groups that the curing agent includes is preferably two or more and more preferably two or three.

As the curing agent, specifically, for example, an amine-based curing agent, a phenol-based curing agent, a guanidine-based curing agent, an imidazole-based curing agent, a naphthol-based curing agent, an acrylic curing agent, an acid anhydride-based curing agent, an active ester-based curing agent, a benzoxazine-based curing agent, a cyanate ester-based curing agent, and the like are exemplified. Among these, an imidazole-based curing agent, an acrylic curing agent, a phenol-based curing agent, and an amine-based curing agent are preferred.

In a case where the curing agent is contained, the content of the curing agent in the resin composition is not particularly limited, but is preferably 1% to 50% by mass and more preferably 1% to 30% by mass of the total solid content in the resin composition.

(Curing Accelerator)

The kind of a random curing accelerator is not particularly limited, and for example, triphenylphosphine, 2-ethyl-4-methylimidazole, a boron trifluoride amine complex, 1-benzyl-2-methylimidazole, and a curing accelerator described in Paragraph [0052] of JP2012-067225A are exemplified.

In a case where the curing accelerator is contained, the content of the curing accelerator in the resin composition is not particularly limited, but is preferably 0.1% to 20% by mass of the total solid content in the resin composition.

(Polymerization Initiator)

In the case of containing the above-described polymerizable monomer, the resin composition preferably contains a polymerization initiator.

Particularly, in a case where the polymerizable monomer has an acryloyl group or a methacryloyl group, the resin composition preferably contains a polymerization initiator described in Paragraph [0062] of JP2010-125782A and Paragraph [0054] of JP2015-052710A.

In a case where the polymerization initiator is contained, the content of the polymerization initiator in the resin composition is not particularly limited, but is preferably 0.1% to 50% by mass of the total solid content in the resin composition.

The kind of the solvent is not particularly limited, and an organic solvent is preferred.

As the organic solvent, for example, ethyl acetate, methyl ethyl ketone, dichloromethane, tetrahydrofuran, and the like are exemplified.

<Application Method>

A method for applying the resin composition is not particularly limited, and, for example, well-known methods such as a roll coating method, a gravure printing method, a spin coating method, a wire bar coating method, an extrusion coating method, a direct gravure coating method, a reverse gravure coating method, a die-coating method, a spraying method, and an inkjet method are exemplified.

In a case where a coated film is formed after application, a drying treatment may be carried out as necessary, and, for example, a method in which hot air of 40° C. to 140° C. is imparted to the resin composition applied onto the base material for 1 to 30 minutes and the like are exemplified.

<Curing Method>

A method for curing the coated film is not particularly limited, and an optimal method is appropriately selected depending on the kinds of the above-described resin binder and the random polymerizable monomer.

The curing method may be, for example, any of a thermal curing reaction or a light curing reaction and is preferably a thermal curing reaction.

The heating temperature in the thermal curing reaction is not particularly limited and may be appropriately selected, for example, in a range of 50° C. to 200° C. In addition, in the case of causing the thermal curing reaction, heating treatments at different temperatures may be carried out a plurality of times.

In addition, the curing reaction may be a semi-curing reaction. That is, a cured substance to be obtained may be in a so-called B stage state (semi-cured state).

[Heat Dissipation Sheet-Attached Device]

A heat dissipation sheet-attached device of the embodiment of the present invention has a device and the heat dissipation sheet of the embodiment of the present invention dispose on the device.

Here, as the device, specifically, for example, semiconductor elements such as CPU and a power device are exemplified.

### EXAMPLES

The present invention will be described in more detail on the basis of examples described below. Materials, amounts used, proportions, processing contents, processing orders, and the like described in the following examples can be appropriately modified within the scope of the present invention. Therefore, the scope of the present invention is not supposed to be interpreted to be limited by the examples described below.

### Comparative Example 1

A resin binder (binder resin) was prepared using a method described in Paragraphs [0094] and [0095] of JP2009-197185A.

Next, SGPS (boron nitride, average particle diameter: 12 μm, manufactured by Denka Company Limited) was added to the prepared resin binder so that the amount reached 24 g with respect to 14.4 g of the resin binder and kneaded, thereby preparing a resin composition.

Next, the prepared resin composition was applied onto a copper foil film (C1020, thickness: 100 μm, manufactured by Nishida Seisakusho) using an applicator so that the dried thickness reached 300 μm, dried with hot air of 130° C. for five minutes to form a coated film, and then the coated film was cured by being heated at 180° C. for one hour, thereby producing a copper foil-attached heat dissipation sheet.

### Comparative Example 2

A polyester film-attached heat dissipation sheet was produced in the same manner as in Comparative Example 1 except for the fact that the resin composition was applied onto a release surface of a polyester film (NP-100A, film thickness: 100 μm, manufactured by Panac Corporation).

### Example 1

<Preparation of Inorganic Particles>

SGPS (boron nitride, average particle diameter: 12 μm, manufactured by Denka Company Limited) (24 g) was classified using a metal mesh having a pore diameter of 100 μm, and inorganic particles A having a particle diameter of 100 μm or less and inorganic particles B having a particle diameter of more than 100 μm were respectively collected.

<Preparation of Resin Compositions>

(Resin Composition A-1)

The inorganic particles A (12.0 g) was added to the resin binder (7.2 g) prepared using the same method as in Comparative Example 1 and kneaded, thereby preparing a resin composition A-1.

(Resin Composition B-1)

The inorganic particles B (12.0 g) was added to the resin binder (7.2 g) prepared using the same method as in Comparative Example 1 and kneaded, thereby preparing a resin composition B-1.

<Production of Heat Dissipation Sheet>

The prepared resin composition B-1 was applied onto a copper foil film (C1020, thickness: 100 μm, manufactured by Nishida Seisakusho) using the applicator so that the dried thickness reached 200 μm and dried with hot air of 130° C. for five minutes, thereby forming a coated film Y.

Next, the prepared resin composition A-1 was applied onto the coated film Y using the applicator so that the dried thickness reached 100 μm and dried with hot air of 130° C. for five minutes, thereby forming a coated film X.

After that, the films were cured under conditions of 180° C. and one hour, and cured films were formed, thereby producing a copper foil-attached heat dissipation sheet.

### Example 2

A polyester film-attached heat dissipation sheet was produced in the same manner as in Example 1 except for the fact that the resin composition B-1 was applied onto a release surface of a polyester film (NP-100A, film thickness: 100 μm, manufactured by Panac Corporation).

### Example 3

<Preparation of Resin Compositions>

(Resin Composition A-2)

The inorganic particles A (24.0 g) was added to the resin binder (7.2 g) prepared using the same method as in Comparative Example 1 and kneaded, thereby preparing a resin composition A-2.

(Resin Composition B-2)

The inorganic particles B (24.0 g) was added to the resin binder (7.2 g) prepared using the same method as in Comparative Example 1 and kneaded, thereby preparing a resin composition B-2.

<Production of Heat Dissipation Sheet>

The prepared resin composition B-2 was applied onto a copper foil film (C1020, thickness: 100 μm, manufactured by Nishida Seisakusho) using the applicator so that the dried thickness reached 250 μm and dried with hot air of 130° C. for five minutes, thereby forming a coated film Y.

Next, the prepared resin composition A-2 was applied onto the coated film Y using the applicator so that the dried thickness reached 50 μm and dried with hot air of 130° C. for five minutes, thereby forming a coated film X.

After that, the films were cured under conditions of 180° C. and one hour, and cured films were formed, thereby producing a polyester film-attached heat dissipation sheet.

### Example 4

A polyester film-attached heat dissipation sheet was produced in the same manner as in Example 3 except for the fact that a resin composition B-3 prepared using a method described below was used instead of the resin composition B-2.

(Resin Composition B-3)

The inorganic particles B (30.0 g) was added to the resin binder (7.2 g) prepared using the same method as in Comparative Example 1 and kneaded, thereby preparing a resin composition B-3.

### Example 5

A polyester film-attached heat dissipation sheet was produced in the same manner as in Example 2 except for the fact that a resin composition A-4 prepared using a method described below was used instead of the resin composition A-1, and a resin composition B-4 prepared using a method described below was used instead of the resin composition B-1.

(Resin Composition A-4)

The inorganic particles A (7.2 g) was added to the resin binder (7.2 g) prepared using the same method as in Comparative Example 1 and kneaded, thereby preparing a resin composition A-4.

(Resin Composition B-4)

The inorganic particles B (7.2 g) was added to the resin binder (7.2 g) prepared using the same method as in Comparative Example 1 and kneaded, thereby preparing a resin composition B-4.

### Example 6

A polyester film-attached heat dissipation sheet was produced in the same manner as in Example 5 except for the fact that the heat dissipation sheet was produced using a method described below.

<Production of Heat Dissipation Sheet>

The prepared resin composition B-4 was applied onto a copper foil film (C1020, thickness: 100 μm, manufactured by Nishida Seisakusho) using the applicator so that the dried thickness reached 250 μm and dried with hot air of 130° C. for five minutes, thereby forming a coated film Y.

Next, the prepared resin composition A-4 was applied onto the coated film Y using the applicator so that the dried thickness reached 50 μm and dried with hot air of 130° C. for five minutes, thereby forming a coated film X.

After that, the films were cured under conditions of 180° C. and one hour, and cured films were formed, thereby producing a polyester film-attached heat dissipation sheet.

### Example 7

A polyester film-attached heat dissipation sheet was produced in the same manner as in Example 5 except for the fact that the heat dissipation sheet was produced using a method described below.

<Production of Heat Dissipation Sheet>

The prepared resin composition B-4 was applied onto a copper foil film (C1020, thickness: 100 μm, manufactured by Nishida Seisakusho) using the applicator so that the dried thickness reached 280 μm and dried with hot air of 130° C. for five minutes, thereby forming a coated film Y.

Next, the prepared resin composition A-4 was applied onto the coated film Y using the applicator so that the dried thickness reached 20 μm and dried with hot air of 130° C. for five minutes, thereby forming a coated film X.

After that, the films were cured under conditions of 180° C. and one hour, and cured films were formed, thereby producing a polyester film-attached heat dissipation sheet.

For each of the produced heat dissipation sheets, the presence proportion of the inorganic particles A in the region X and the presence proportion of the inorganic particles B in the region Y were computed using the above-described method. The results are shown in Table 1 and Table 2.

For each of the produced heat dissipation sheets, a region from the air interface-side surface of the cured film to ⅓ of the overall thickness of the heat dissipation sheet in the thickness direction was regarded as the region X, and a region from the base material interface-side surface of the cured film to ⅔ of the overall thickness of the heat dissipation sheet in the thickness direction was regarded as the region Y.

[Heat Dissipation Property]

The copper foil film or the polyester film was released from each of the produced heat dissipation sheets, then, the thermal conductivity was measured using a method described below, and the heat dissipation property was evaluated using the following standards. The results are shown in Table 1 and Table 2.

<Measurement of Thermal Conductivity>

(1) The thermal diffusion ratio of each heat dissipation sheet in the thickness direction was measured using “ai-Phase Mobile 1u” manufactured by ai˜Phase Co., Ltd.

(2) The specific gravity of each heat dissipation sheet was measured using a balance “XS204” (“solid specific gravity measurement kit” used) manufactured by Mettler Toledo.

(3) The specific heat of each heat dissipation sheet at 25° C. was obtained under a temperature rise condition of 10° C./minute using “DSC320/6200” manufactured by Seiko Instruments Inc. and software of DSC7.

(4) The obtained thermal diffusion ratio was multiplied by the specific gravity and the specific heat, thereby computing the thermal conductivity of each heat dissipation sheet.

(Evaluation Standards)

“A”: 14 W/m·K or more

“B”: 10 W/m·K or more and less than 14 W/m·K

“C”: Less than 6 W/m·K

TABLE 1

| | | | Heat dissipation sheet | | | | |
|---|---|---|---|---|---|---|---|
| | Base material | | | Inorganic particles | | | Heat |
| | | Thickness | Resin | (not classified) | | Thickness | dissipation |
| | Material | (μm) | binder | Kind | Content *1 | (μm) | property |
| Comparative | Copper | 100 | Epoxy | Boron | 167 | 300 | C |
| Example 1 | | | | nitride | | | |
| Comparative | PET | 100 | Epoxy | Boron | 167 | 300 | C |
| Example 2 | | | | nitride | | | |

*1 Parts by mass of entire heat dissipation sheet with respect to 100 parts by mass of resin binder

TABLE 2

| | | | Heat dissipation sheet | | | | | | | | | |
|---|---|---|---|---|---|---|---|---|---|---|---|---|
| | Base material | | | Inorganic particles A | | | | Inorganic particles B | | | | Heat |
| | | Thickness | Resin | | Content | Proportion *2 | Thickness | | Content | Proportion *3 | Thickness | dissipation |
| | Material | (μm) | binder | Kind | *1 | [%] | (μm) | Kind | *1 | [%] | (μm) | property |
| Example 1 | Copper | 100 | Epoxy | Boron | 83 | 99% | 100 | Boron | 83 | 99% | 200 | B |
| | | | | nitride | | | | nitride | | | | |
| Example 2 | PET | 100 | Epoxy | Boron | 83 | 99% | 100 | Boron | 83 | 99% | 200 | B |
| | | | | nitride | | | | nitride | | | | |
| Example 3 | PET | 100 | Epoxy | Boron | 167 | 99% | 50 | Boron | 167 | 79% | 250 | A |
| | | | | nitride | | | | nitride | | | | |
| Example 4 | PET | 100 | Epoxy | Boron | 167 | 99% | 50 | Boron | 208 | 79% | 250 | A |
| | | | | nitride | | | | nitride | | | | |
| Example 5 | PET | 100 | Epoxy | Boron | 50 | 99% | 100 | Boron | 50 | 99% | 200 | B |
| | | | | nitride | | | | nitride | | | | |
| Example 6 | PET | 100 | Epoxy | Boron | 50 | 99% | 50 | Boron | 50 | 80% | 250 | B |
| | | | | nitride | | | | nitride | | | | |
| Example 7 | PET | 100 | Epoxy | Boron | 50 | 99% | 20 | Boron | 50 | 71% | 280 | B |
| | | | | nitride | | | | nitride | | | | |

*1 Parts by mass of entire heat dissipation sheet with respect to 100 parts by mass of resin binder
*2 Presence proportion of inorganic particles A in region X in total number of inorganic particles A
*3 Presence proportion of inorganic particles B in region Y in total number of inorganic particles B

From the results shown in Table 1 and Table 2, it was found that, in the case of using the inorganic particles A having a particle diameter of 100 μm or less and the inorganic particles B having a particle diameter of more than 100 μm without classifying the inorganic particles, the presence proportion of the inorganic particles A in the region X of the heat dissipation sheet became less than 80%, the presence proportion of the inorganic particles B in the region Y of the heat dissipation sheet became less than 70%, and the heat dissipation property deteriorated (Comparative Examples 1 and 2).

On the other hand, it was found that, in a case where the inorganic particles A having a particle diameter of 100 μm or less and the inorganic particles B having a particle diameter of more than 100 μm were classified, the presence proportion of the inorganic particles A in the region X of the heat dissipation sheet was set to 80% or more, and the presence proportion of the inorganic particles B in the region Y of the heat dissipation sheet was set to 70% or more, the heat dissipation property became favorable (Examples 1 to 7).

In addition, from these results, it is possible to infer that, in a case where the presence proportion of the inorganic particles A in the region X of the heat dissipation sheet is set to 80% or more, and the presence proportion of the inorganic particles B in the region Y of the heat dissipation sheet is set to 70% or more, not only in the evaluation results for which a thermal conductivity measurement instrument but also in the joining of the heat dissipation sheet to a device or a heat sink, a gap is not easily generated, and the heat dissipation property becomes favorable.

### Explanation of References

1: resin binder

2: inorganic particles A

3: inorganic particles B

4: one surface

5: the other surface

T: overall thickness

X: region X

Y: region Y

10: heat dissipation sheet

What is claimed is:

1. A heat dissipation sheet comprising:
a resin binder; and
inorganic particles,
wherein the inorganic particles include inorganic particles A having a particle diameter of 100 μm or less and inorganic particles B having a particle diameter of more than 100 μm,
80% or more of all of the inorganic particles A are present in a region X from one surface of the heat dissipation sheet to ⅓ of an overall thickness of the heat dissipation sheet in a thickness direction, and
70% or more of all of the inorganic particles B are present in a region Y from the other surface of the heat dissipation sheet to ⅔ of the overall thickness of the heat dissipation sheet in the thickness direction.

2. The heat dissipation sheet according to claim 1,
wherein the thickness is 200 to 300 μm.

3. The heat dissipation sheet according to claim 1,
wherein a content of the inorganic particles A is 5 to 150 parts by mass with respect to 100 parts by mass of the resin binder.

4. The heat dissipation sheet according to claim 2,
wherein a content of the inorganic particles A is 5 to 150 parts by mass with respect to 100 parts by mass of the resin binder.

5. The heat dissipation sheet according to claim 1,
wherein a content of the inorganic particles B is 50 to 500 parts by mass with respect to 100 parts by mass of the resin binder.

6. The heat dissipation sheet according to claim 2,
wherein a content of the inorganic particles B is 50 to 500 parts by mass with respect to 100 parts by mass of the resin binder.

7. The heat dissipation sheet according to claim 3,
wherein a content of the inorganic particles B is 50 to 500 parts by mass with respect to 100 parts by mass of the resin binder.

8. The heat dissipation sheet according to claim 1,
wherein the inorganic particle is at least one inorganic substance selected from the group consisting of an inorganic nitride and an inorganic oxide.

9. The heat dissipation sheet according to claim 2,
wherein the inorganic particle is at least one inorganic substance selected from the group consisting of an inorganic nitride and an inorganic oxide.

10. The heat dissipation sheet according to claim 3,
wherein the inorganic particle is at least one inorganic substance selected from the group consisting of an inorganic nitride and an inorganic oxide.

11. The heat dissipation sheet according to claim 5,
wherein the inorganic particle is at least one inorganic substance selected from the group consisting of an inorganic nitride and an inorganic oxide.

12. The heat dissipation sheet according to claim 8,
wherein the inorganic nitride contains at least one selected from the group consisting of boron nitride and aluminum nitride.

13. The heat dissipation sheet according to claim 8,
wherein the inorganic oxide contains at least one selected from the group consisting of titanium oxide, aluminum oxide, and zinc oxide.

14. The heat dissipation sheet according to claim 1,
wherein the resin binder is a cured substance obtained by curing a curable composition containing a polymerizable monomer.

15. The heat dissipation sheet according to claim 2,
wherein the resin binder is a cured substance obtained by curing a curable composition containing a polymerizable monomer.

16. The heat dissipation sheet according to claim 3,
wherein the resin binder is a cured substance obtained by curing a curable composition containing a polymerizable monomer.

17. The heat dissipation sheet according to claim 5,
wherein the resin binder is a cured substance obtained by curing a curable composition containing a polymerizable monomer.

18. The heat dissipation sheet according to claim 8,
wherein the resin binder is a cured substance obtained by curing a curable composition containing a polymerizable monomer.

19. The heat dissipation sheet according to claim 14,
wherein the polymerizable monomer has at least one polymerizable group selected from the group consisting of an acryloyl group, a methacryloyl group, an oxiranyl group, and a vinyl group.

20. A heat dissipation sheet-attached device comprising:
a device; and
the heat dissipation sheet according to claim 1 disposed on the device.
